(19) United States
(12) Patent Application Publication
(10) Pub. No.: US 2015/0171367 A1
(43) Pub. Date: Jun. 18, 2015

(54) ORGANIC LIGHT-EMITTING DISPLAY APPARATUS AND METHOD OF MANUFACTURING THE SAME

(71) Applicant: SAMSUNG DISPLAY CO., LTD., Yongin-City (KR)

(72) Inventor: Seung-Jun Moon, Yongin-City (KR)

(73) Assignee: SAMSUNG DISPLAY CO., LTD., Yongin-City (KR)

(21) Appl. No.: 14/225,390

(22) Filed: Mar. 25, 2014

(30) Foreign Application Priority Data
Dec. 18, 2013 (KR) 10-2013-0158682

(51) Int. Cl. H01L 51/52; H01L 51/56; H01L 27/32

(52) U.S. Cl. CPC H01L 51/5253; H01L 27/32; H01L 51/56

(57) ABSTRACT

An organic light-emitting display apparatus includes a substrate, a display portion on the substrate, an organic layer extending over the display portion, an inorganic layer extending over the organic layer, and a dam surrounding an outer perimeter of the organic layer. The dam may include a groove configured to accommodate a portion of the organic layer extending beyond a perimeter of the dam surrounding the organic layer. A method of manufacturing an organic light-emitting display apparatus includes forming a display portion on a substrate, forming a dam defining a groove in a region spaced from the display portion, forming an organic layer over the display portion and extending up to the region spaced from the display portion such that the organic layer is surrounded by the dam, and forming an inorganic layer over the organic layer.

### CROSS-REFERENCE TO RELATED APPLICATION

This application claims priority to and the benefit of Korean Patent Application No. 10-2013-0158682, filed on Dec. 18, 2013, in the Korean Intellectual Property Office, the entire disclosure of which is incorporated herein by reference.

### BACKGROUND

1. Field

Aspects of the present invention relate to organic light-emitting display apparatuses and methods of manufacturing the organic light-emitting display apparatuses.

2. Description of the Related Art

Organic light-emitting display apparatuses generally include a display portion having a structure in which an emission layer formed of an organic material is positioned between an anode electrode and a cathode electrode. When a voltage is applied to the anode electrode and the cathode electrode of the apparatuses, holes injected from each of the anode electrode and the cathode electrode are recombined with each other to generate an exciton. When the exciton changes from an excited state to a ground state, light is emitted forming an image on the apparatus.

If the emission layer of the display portion comes into contact with moisture, an emission characteristic of the display portion may deteriorate, thus an encapsulation member is typically used to cover the display portion to prevent such deterioration. Thin film encapsulation in which organic layers and inorganic layers are alternately stacked is one type of encapsulation member.

### SUMMARY

One or more embodiments of the present invention relate to organic light-emitting display apparatuses. Embodiments of the present invention also relate to organic light-emitting display apparatuses having an improved structure of thin film encapsulation and methods of manufacturing the same.

According to one or more embodiments of the present invention, an organic light-emitting display apparatus includes a substrate, a display portion on the substrate, an organic layer extending over the display portion, an inorganic layer extending over the organic layer, and a dam surrounding an outer perimeter of the organic layer, wherein the dam includes a groove configured to accommodate a portion of the organic layer extending beyond a perimeter of the dam surrounding the organic layer.

The dam may further include a single layer surrounding the outer perimeter of the organic layer. In another embodiment, the dam may further include a plurality of layers surrounding the outer perimeter of the organic layer.

The inorganic layer may extend to an outer edge of the dam.

The dam may further include a bottom surface contacting the substrate, a plurality of wall surfaces integrally formed with the bottom surface and extending upward from the bottom surface, and wherein the groove may be defined by an opening surrounded by the bottom surface and the plurality of wall surfaces of the dam.

According to one or more embodiments of the present invention, a method of manufacturing an organic light-emitting display apparatus includes forming a display portion on a substrate; forming a dam defining a groove in a region spaced from the display portion; forming an organic layer over the display portion and extending up to the region spaced from the display portion such that the organic layer is surrounded by the dam; and forming an inorganic layer over the organic layer.

The dam may be formed of a single layer. In another embodiment, the dam may be formed of a plurality of layers.

The inorganic layer may extend to and outer edge of the dam.

The groove may be defined by an opening sunken from an upper surface of the dam into the inside such that a part of an outer perimeter of the organic layer is contained in the accommodated in the groove.

Additional aspects will be set forth in part in the description which follows and, in part, will be apparent from the description, or may be learned by practice of the presented embodiments, or as appreciated by those skilled in the art.

### BRIEF DESCRIPTION OF THE DRAWINGS

These and/or other aspects will become apparent and more readily appreciated from the following description of the embodiments, taken in conjunction with the accompanying drawings, in which:

FIG. 1 is a plan view of an organic light-emitting display apparatus, according to an embodiment of the present invention;

FIG. 2 is a cross-sectional view taken along the line A-A of FIG. 1;

FIG. 3 is a partially expanded plan view including pixels of a display portion of the organic light-emitting display apparatus of FIGS. 1 and 2;

FIG. 4 is an equivalent schematic circuit diagram of one of the pixels shown in FIG. 3;

FIG. 5 is a cross-sectional view taken along the line B-B of FIG. 3;

FIG. 6 is a cross-sectional view taken along the line C-C of FIG. 3;

FIGS. 7A through 7D are diagrams sequencing a process of manufacturing the organic light-emitting display apparatus of the embodiments shown in FIGS. 1 and 2; and

FIG. 8 is a cross-sectional view of an organic light-emitting display apparatus according to another embodiment of the present invention.

### DETAILED DESCRIPTION

Reference will now be made in detail to various embodiments of the present invention, examples of which are illustrated in the accompanying drawings, wherein like reference numerals refer to like elements throughout. The present embodiments may have different forms and should not be construed as being limited to the descriptions set forth herein. Accordingly, the embodiments are merely described below, by reference to the figures, to explain aspects of the present description.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on,” or “on” another layer, region, or component, it can be directly or indirectly formed on or on the other layer, region, or component. That is, for example, intervening layers, regions, or components may also be present.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

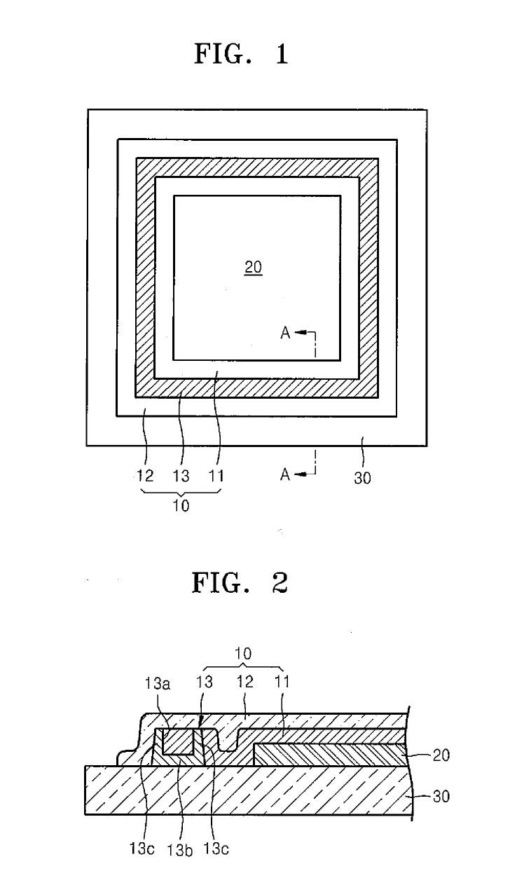

FIG. 1 is a plan view of an organic light-emitting display apparatus, according to an embodiment of the present invention. FIG. 2 is a cross-sectional view taken along the line A-A of FIG. 1.

The organic light-emitting display apparatus according to an embodiment has a structure in which a display portion 20 that displays an image is on a substrate 30 with a thin film encapsulation 10 covering and protecting the display portion 20.

The thin film encapsulation 10, according to this embodiment, includes an organic layer 11 directly covering the display portion 20 and an inorganic layer 12 on the organic layer 11. The organic layer 11 mainly provides flexibility to the organic light-emitting display apparatus. The inorganic layer 12 firmly prevents oxygen or moisture from permeating through to the display portion 20. Thus, the display portion 20, according to this embodiment, is sealed between the substrate 30 and the thin film encapsulation 10.

The organic layer 11 may be formed of a flexible organic material, for example, in some embodiments, the organic layer 11 may be formed of polyurea or polyacrylate.

The inorganic layer 12 may be formed of an inorganic material having a waterproof or water-resistant characteristic. For example, in some embodiments, the inorganic layer 12 may be formed of SiNx, Al₂O₃, SiO₂, or TiO₂.

In these embodiments, since the organic layer 11 of the thin film encapsulation 10 has minimal ability to prevent moisture movement as compared to the inorganic layer 12, if an end portion of the organic layer 11 spreads to an outer edge of a region covered by the inorganic layer 12, the result would be the creation of a path through which external moisture may permeate into the display portion 20. Thus, the thin film encapsulation 10 may include a dam 13 for effectively regulating a range of the organic layer 11 to prevent the path of moisture movement from being created, according to an embodiment.

The dam 13, according to this embodiment, is formed outside the display portion 20 in order to regulate a region of the organic layer 11, and may include an accommodation groove 13a surrounded by a floor surface 13b and two wall surfaces 13c, as shown in FIG. 2. Thus, according to this embodiment, the dam 13, itself, may function as a dam for preventing the organic layer 11 from spreading to the outer edge of the organic light emitting display apparatus where the inorganic layer 12 is extends, as well as containing any part of the organic layer 11 that may extend over the dam 13 in the accommodation groove 13a to prevent it from spreading to an outer edge. Thus, according to this embodiment, the dam 13 functions to prevent the organic layer 11 from extending to the outer edge, and the accommodation groove 13a functions to prevent the organic layer 11 from extending beyond the dam 13 to the outer edge.

The dam 13 will be described in further detail, below. Further details of the structure of the display portion 20 will now be described.

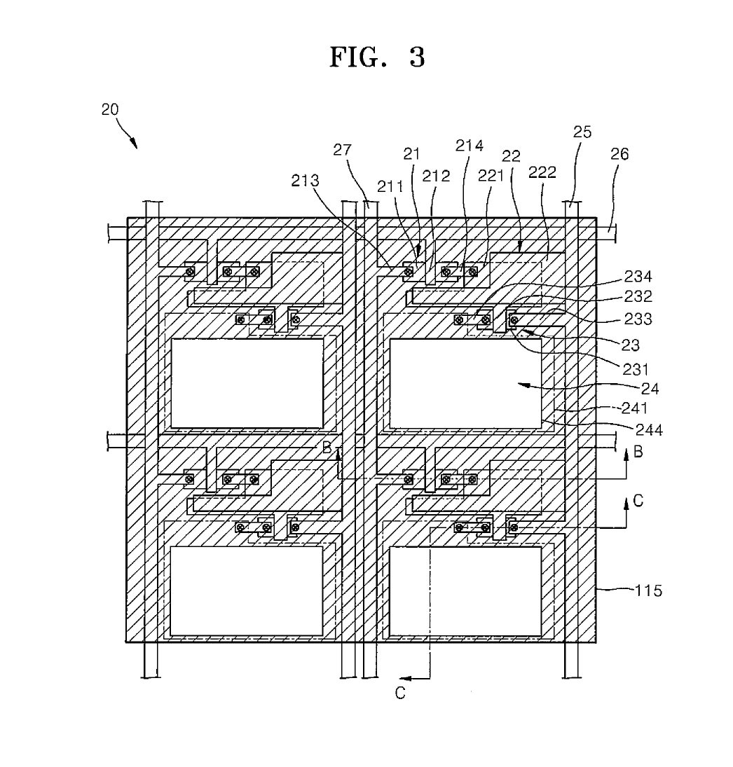

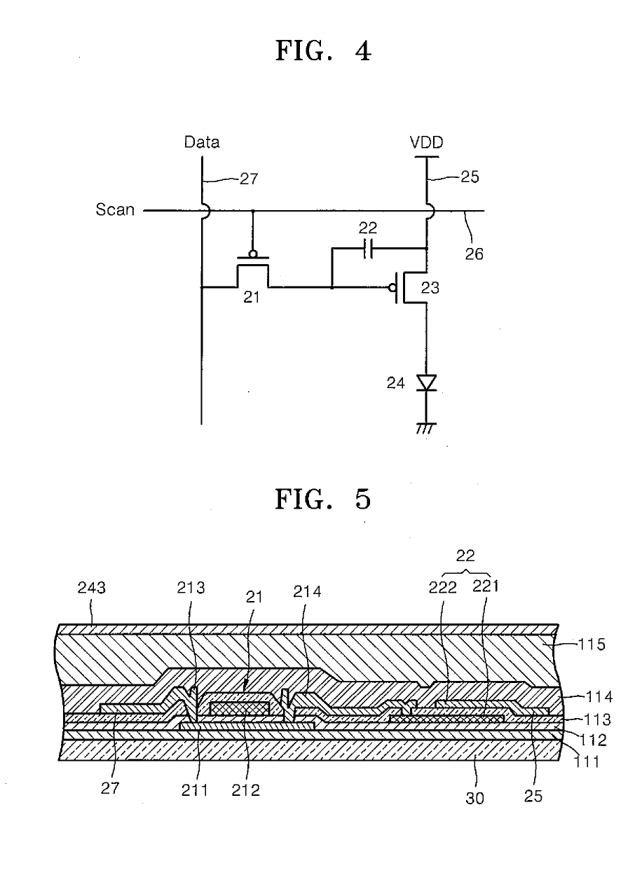

In an embodiments where the display portion 20 is expanded, multiple pixels may be present as shown in the partially expanded view in FIG. 3. A structure of one pixel of these multiple pixels is expressed as an equivalent schematic circuit diagram as shown in FIG. 4.

As shown, each pixel according to this embodiment generally includes at least two thin film transistors (TFTs), including a first TFT 21 for switching and a second TFT 23 for driving, a capacitor 22, and an organic light-emitting device 24 (hereinafter referred to as an “EL device”).

The first TFT 21, according to this embodiment, is driven by a scan signal (Scan) applied to a gate line 26, and transmits a data line (Data) applied to a data line 27.

The second TFT 23, according to this embodiment, determines an amount of current to enter into the EL device 24 according to the data signal Data transmitted by the first TFT 21, i.e., a voltage difference (Vgs) between a gate and a source.

The capacitor 22, according to this embodiment, stores the data signal Data transmitted by the first TFT 21 for a frame.

To implement a circuit according to this embodiment, an organic light-emitting display apparatus has a structure as shown in the embodiments of FIGS. 3, 5, and 6, which will be described in further detail below.

As shown in the embodiments of FIGS. 3, 5, and 6, a buffer layer 111 is positioned on the substrate 30, and the first TFT 21, the second TFT 23, the capacitor 22, and the EL device 24 are positioned on the buffer layer 111.

As shown in the embodiments of FIGS. 3 and 5, the first TFT 21 includes a first active layer 211 on the buffer layer 111, a gate insulating layer 112 on the first active layer 211, and a gate electrode 212 on the gate insulating layer 112.

The first active layer 211, according to an embodiment, may be formed as an amorphous silicon thin film or a polycrystalline silicon thin film. The first active layer 211, according to an embodiment, includes source and drain regions doped with high concentration N type or P type impurities. Alternatively, the first active layer 211, according to another embodiment, may be formed of an oxide semiconductor. For example, the oxide semiconductor forming the first active layer 211, according to this embodiment, may include an oxide of a material selected from Group 12, 13, or 14 metal elements, such as zinc (Zn), indium (In), gallium (Ga), tin (Sn), cadmium (Cd), germanium (Ge), or hafnium (Hf), and any combinations thereof. For example, in one embodiment, the first active layer 211 may include G-I-Z-O [(In₂O₃)a(Ga₂O₃)b(ZnO)c] (where a, b, and c are real numbers satisfying a condition that a≧0, b≧0, and c>0).

The gate insulating layer 112, according to an embodiment, is on the first active layer 211, and the gate electrode 212 is on a predetermined region of the gate insulating layer 112. The gate electrode 212, according to this embodiment, is connected to the gate line 26 that applies a TFT on/off signal.

In an embodiment, an inter-insulator 113 may be on the gate electrode 212. In an embodiment, a source electrode 213 and a drain electrode 214 are respectively formed to contact the source and drain regions of the first active layer 211 through contact holes. The source electrode 213, according to this embodiment, is connected to the data line 27 of FIG. 3 and supplies a data signal to the first active layer 211. The drain electrode 214, according to this embodiment, is connected to a first charging electrode 221 of the capacitor 22 and supplies power to the capacitor 22.

According to an embodiment, a passivation layer 114, which may be formed of an inorganic material such as SiO₂, SiNx, etc., may be positioned on the source electrode 213 and the drain electrode 214. A planarization layer 115, according to an embodiment, may be formed of an acryl, polyimide, BCB, etc. material, and may be positioned on the passivation layer 114.

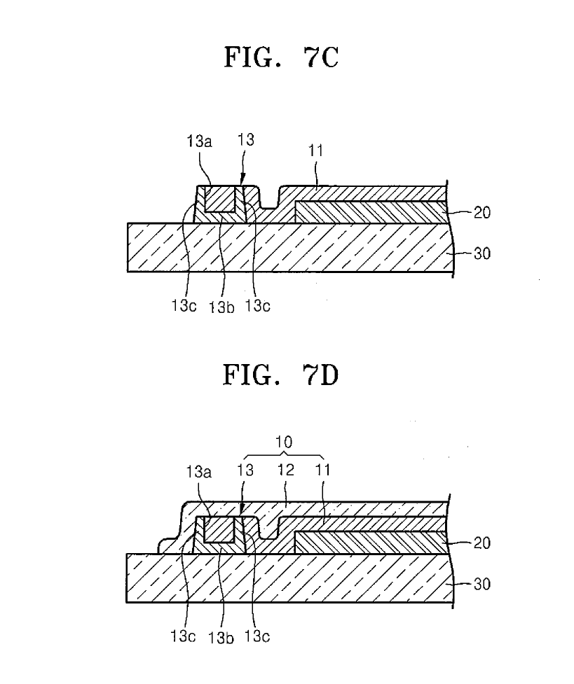

The capacitor 22 for charging, according to an embodiment, is between the first TFT 21 and the second TFT 23 and stores a driving voltage necessary for driving the second TFT 23 for one frame. As shown in the embodiments of FIGS. 5 and 7, the capacitor 22 may include a first charging electrode 221 connected to the drain electrode 214 of the first TFT 21, a second charging electrode 222 overlapping with an upper portion of the first charging electrode 221 and electrically connected to a driving power line 25 that applies driving power, and the inter-insulator 113 between the first charging electrode 221 and the second charging electrode 222 and used as a dielectric substance.

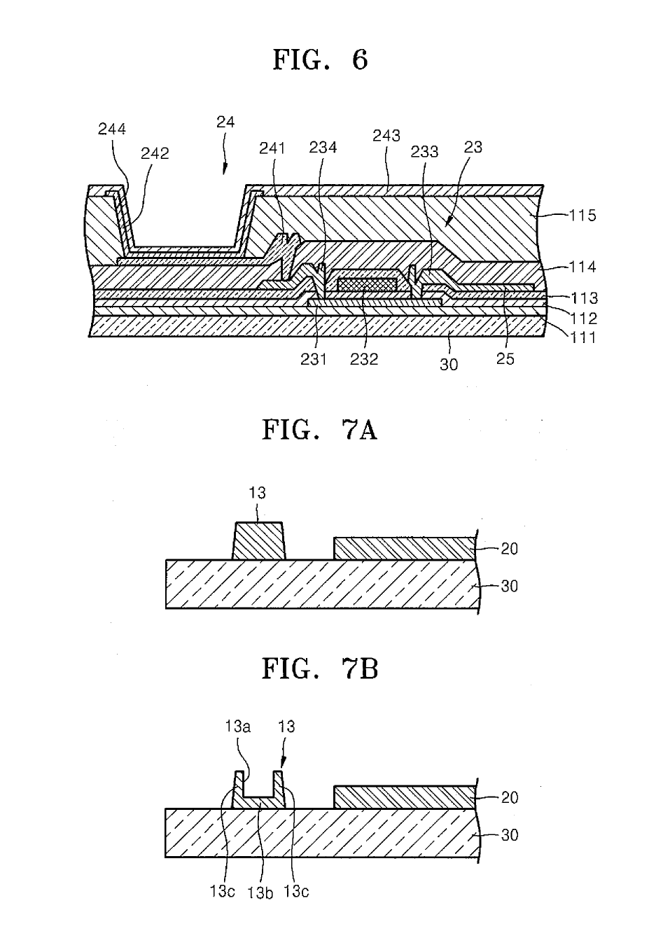

A second active layer 231, according to an embodiment, may be on the buffer layer 111 in the second TFT 23, as shown in FIGS. 3 and 6. The second active layer 231, according to this embodiment, includes source and drain regions doped with high concentration N type or P type impurities. The second active layer 231, according to an embodiment, may also be formed of an oxide semiconductor. For example, the second active layer 231, according to this embodiment, may be formed of an oxide semiconductor including an oxide of a material selected from Group 12, 13, or 14 metal elements, such as zinc (Zn), indium (In), gallium (Ga), tin (Sn), cadmium (Cd), germanium (Ge), or hafnium (Hf), and any combinations thereof. For example, in one embodiment, the second active layer 231 may include G-I-Z-O [(In₂O₃)a(Ga₂O₃)b(ZnO)c] (where a, b, and c are real numbers satisfying a condition that a≧0, b≧0, and c>0). In an embodiment, a second gate electrode 232 that is connected to the first charging electrode 221 of the capacitor 22 and supplies a TFT on/off signal may be on the second active layer 231 with the gate insulating layer 112 between the second active layer 231 and the second gate electrode 232. A second source electrode 233, according to an embodiment, may be connected to the driving power line 25 supplying a reference voltage to the second active layer 231 for driving, and a second drain electrode 234 connecting the second TFT 23 and the EL device 24 and applying driving power to the EL device 24 may be on the second gate electrode 232, according to the embodiment. The inter-insulator 113 in this embodiment is between the second gate electrode 232, the second source electrode 233, and the second drain electrode 234. The passivation layer 114, according to this embodiment, is between the second source electrode 233 and the second drain electrode 234, and between the first electrode 241 that is an anode electrode of the EL device 24.

The insulating planarization layer 115, according to an embodiment, may be formed of a material such as acryl, etc, and positioned on the first electrode 241. An opening 244 may be defined in the planarization layer 115, and then the EL device 24 may be formed.

The EL device 24, according to an embodiment, emits red, green, and blue light according to a flow of current, and displays predetermined image information. The EL device 24, according to this embodiment, may include the first electrode 241 that is the anode electrode connected to the second drain electrode 234 of the second TFT 23 and receives a positive power supply from the second drain electrode 234, a second electrode 243 that is a cathode electrode configured to cover whole pixels and supplies negative power, and an emission layer 242 between the first electrode 241 and the second electrode 243 that emits light.

A hole injection layer (HIL), a hole transport layer (HTL), an emission layer (EML), an electron transport layer (ETL), and an electron injection layer (EIL) may be stacked adjacent to the emission layer 242, according to embodiments of the present invention.

According an embodiment, the emission layer 242 may be separately formed for each pixel such that pixels that emit red, green, and blue light form a single unit pixel as shown in the embodiment of FIG. 6. Alternatively, the emission layer 242, according to another embodiment, may be commonly formed on a whole pixel region regardless of the positions of the pixels. In this embodiment, the emission layer 242 may be formed by vertically stacking or mixing, for example, layers including an emission material that emits the red, green, and blue lights. A combination of other colors may be possible in other embodiments where the emission layer 242 may be able to emit white light. A color conversion layer that converts the emitted white light into a predetermined color or a color filter may be further included, in other embodiments.

The emission layer 242, according to these embodiments, is highly vulnerable to moisture, and thus if moisture permeates into the display portion 20, an image forming characteristic of the organic light-emitting display apparatus may rapidly deteriorate.

A structure of the organic light-emitting display apparatus according to an embodiment of the present invention will now be described with reference back to FIGS. 1 and 2.

The display portion 20, according to an embodiment, may be formed by using the above-described pixels as shown in FIG. 3. An image may be formed on the display portion 20. In this embodiment, the TFTs 21 and 23, the capacitors 22, and the EL devices 24 shown in FIGS. 3, 5, and 6 may be installed in the display portion 20.

The thin film encapsulation 10 is placed over the display portion 20, according to an embodiment, to protect the display portion 20 from external moisture and air. The thin film encapsulation 10 in this embodiment has the organic layer 11 and the inorganic layer 12 sequentially stacked. More specifically, the organic layer 11, according to an embodiment, directly covers the display portion 20, and the inorganic layer 12 covers the organic layer 11. Thus, the thin film encapsulation 10 according to this embodiment in which the organic layer 11 and the inorganic layer 12 are sequentially stacked, may have both a moisture movement prevention function and flexibility function.

As described above, the dam 13, according to embodiments, may regulate a region of the organic layer 11 to prevent creation of a moisture movement path through the organic layer 11. In these embodiments, the wall surface 13c of the dam 13 of the display portion 20 may prevent the organic layer 11 from extending to the outer edge, and, if a part of the organic layer 11 does extend beyond the dam 13, allows that extension to be contained in the accommodation groove 13a to prevent its further extension to the outer edge. Thus, the dam 13 according to an embodiment having the above-described structure, may prevent the organic layer 11 from extending to the outer edge beyond a region covered by the inorganic layer 12, thus, reducing the possibility of moisture movement to the display portion 20 from the outer edge through the organic layer 11.

The organic light-emitting display apparatus according to embodiments having the above-described structure may be manufactured through a process as sequenced in FIGS. 7A through 7D.

According to an embodiment, a body of the dam 13 may be formed in a region outside the display portion 20 on the substrate 30, as shown in FIG. 7A. In an embodiment, the dam 13 may be formed, for example, by using a deposition process using a mask, and may be formed of a material capable of patterning by exposure and etching.

Next, the accommodation groove 13a sunken from an upper surface of the dam 13 into the inside thereof may be defined, according to an embodiment, as shown in FIG. 7B. The accommodation groove 13a may be defined in the upper surface of the dam 13 after exposing and etching, for example, a corresponding region of the dam 13.

The organic layer 11 covering the display portion 20 may be formed as shown in the embodiment of FIG. 7C. In this embodiment, a region of the organic layer 11 may be regulated by the dam 13. If a portion of the organic layer 11 extends beyond the dam 13, since the portion is contained in the accommodation groove 13a, according to this embodiment, there possibility of continuously spreading the organic layer 11 to the outside edges is reduced.

Next, placement of the inorganic layer 12 over the organic layer 11 and the dam 13, as shown in the embodiment of FIG. 7D, may complete the thin film encapsulation 10 process according to these embodiments.

Therefore, the dam 13, according to these embodiments, may effectively prevent the organic layer 11 from extending to the outer edge, such that the organic layer 11 remains entirely covered by the inorganic layer 12 having outstanding waterproof properties, and thus implement a highly stable anti-moisture movement property in the thin film encapsulation 10.

In these embodiments, an outer boundary of the organic layer 11 is strictly regulated by the dam 13 and is wholly covered by the inorganic layer 12, thereby limiting a possibility of permeating external moisture into the display portion 20 through the organic layer 11. Thus, a performance deterioration problem of the display portion 20 due to permeation of oxygen or moisture may be greatly avoided.

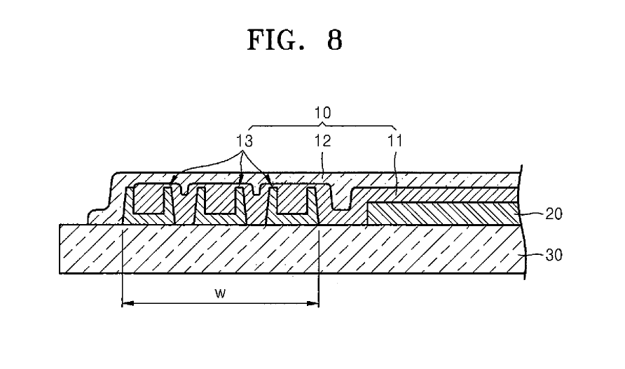

Although the dam 13 may be formed in a single layer in a region outside the display portion 20, as described in the previous embodiments, the dam 13 may also be formed in several layers, as shown in the embodiment of FIG. 8. In this embodiment, a possibility of the organic layer 11 extending to the outer edge may be more strictly prevented. However, in this embodiment, a dead space outside the display portion 20 may increase, and thus a width W of an overall region of the dam 13 on the substrate 30 may be large, for example up to 5 millimeters (mm) in width.

It should be understood that the exemplary embodiments described herein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention, and as further defined by the following claims.

What is claimed is:

1. An organic light-emitting display apparatus comprising:
a substrate, a display portion on the substrate, an organic layer extending over the display portion, an inorganic layer extending over the organic layer, and a dam surrounding an outer perimeter of the organic layer,
wherein the dam comprises a groove configured to accommodate a portion of the organic layer extending beyond a perimeter of the dam surrounding the organic layer.

2. The organic light-emitting display apparatus of claim 1, wherein the dam further comprises a single layer surrounding the outer perimeter of the organic layer.

3. The organic light-emitting display apparatus of claim 1, wherein the dam further comprises a plurality of layers surrounding the outer perimeter of the organic layer.

4. The organic light-emitting display apparatus of claim 1, wherein the inorganic layer extends to an outer edge of the dam.

5. The organic light-emitting display apparatus of claim 1, wherein the dam further comprises a bottom surface contacting the substrate, a plurality of wall surfaces integrally formed with the bottom surface and extending upward from the bottom surface, and wherein the groove is defined by an opening surrounded by the bottom surface and the plurality of wall surfaces of the dam.

6. A method of manufacturing an organic light-emitting display apparatus, the method comprising:
forming a display portion on a substrate;
forming a dam defining a groove in a region spaced from the display portion;
forming an organic layer over the display portion and extending up to the region spaced from the display portion such that the organic layer is surrounded by the dam; and
forming an inorganic layer over the organic layer.

7. The method of claim 6, wherein the dam comprises a single layer.

8. The method of claim 6, wherein the dam comprises a plurality of layers.

9. The method of claim 6, wherein the inorganic layer extends to an outer edge of the dam.

10. The method of claim 6, wherein the groove is defined by an opening sunken from an upper surface of the dam into the inside such that a part of an outer perimeter of the organic layer is accommodated in the groove.
